(19) United States
(12) Patent Application Publication
(10) Pub. No.: US 2009/0044911 A1
(43) Pub. Date: Feb. 19, 2009

(54) VACUUM PROCESSOR

(75) Inventor: Fumihide SATO, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/190,045

(22) Filed: Aug. 12, 2008

(30) Foreign Application Priority Data
Aug. 13, 2007 (JP) 2007-210845

(51) Int. Cl. H01L 21/306; C23C 14/56

(52) U.S. Cl. 156/345.51; 204/298.15; 118/728

(57) ABSTRACT

A vacuum processor includes: a chamber; a pump which keeps the inside of the chamber in a vacuum state by; a connection part which connects the chamber with the pump and is formed with a gas passage therein. An inner wall of the connection part is provided with a capturing part capturing particles in the passage. The capturing part has a fibrous substance facing the passage and disposed along the passage. The fibrous substance is provided to capture particles. A peripheral part of the woven cloth of the fibrous substance is folded to a back side of the unwoven cloth and the front end of the peripheral part of the woven cloth is interfolded to the back side of the unwoven cloth.

This application is based on Japanese patent application No. 2007-210845, the content of which is incorporated hereinto by reference.

### BACKGROUND OF THE INVENTION

1. Field of the Invention

The present invention relates to a vacuum processor.

2. Description of the Related Art

Conventionally, a vacuum processor, such as a CVD apparatus, a sputtering apparatus or a dry etching apparatus, has been used to manufacture semiconductor elements and electronic parts. In such apparatuses, an object to be processed, such as a semiconductor substrate is placed in a chamber and the internal chamber is kept a vacuum state for treatment, such as thin-film formation.

If particles adhere to the semiconductor substrate, yield decreases. Accordingly, various approaches have been made.

Japanese Patent Application Laid-Open Nos. 60-227421, 2001-338906 and 7-312363 have disclosed a technology of providing an adhesive coating layer over the whole chamber, respectively.

Japanese Patent Application Laid-Open No. 2001-259328 has disclosed a technology of providing a filter between a pump and a process chamber. In addition, Japanese Patent Application Laid-Open No. 2004-247680 has disclosed a technology of capturing particles generated in a plasma reactor with an electrode to which a potential has been applied, using charges borne in plasma.

In addition, such approaches as disclosed in Japanese Patent Application Laid-Open Nos. 3-118815 and 2007-180467 have been proposed. The apparatus described in Japanese Patent Application Laid-Open No. 3-118815 has been constructed by covering a pipe inner wall connected to a vacuum container with an adhesive material and making the adhesive material adsorb dust generated in the pipe. In Japanese Patent Application Laid-Open No. 2007-180467, a flocculent body is disposed inside a connecting pipe for connecting a processing chamber of a substrate processing apparatus with an exhaust pump. The flocculent body, made of, for example, stainless felt or fluoroethylene resin felt, captures particles.

In recent years, to keep the inside of a vacuum container of a vacuum apparatus in a higher vacuum, a pump having rotary blades for a turbo molecular pump (TMP) is used as a pump for exhausting the inside of the vacuum container has been used. Studying of the present inventor has indicated that in the vacuum processor, particles adhering to the periphery of the pump drop onto the pump and are bounced by the pump rotary blades. The pump rotary blades rotate at a high speed, for example, approximately 36,000 revolutions/sec and therefore it is very difficult for the particles dropped onto the pump to pass through between vanes of the rotary blades. Hence, the particles are bounced by the pump rotary blades. The bounced particles are bounced about inside the pipe, but the speed of the particles bounced by the pump rotary blades is very high. Accordingly, it is thought that adhesive material in the pipe is difficult to be captured. Specifically, it is estimated that the adhesive material disclosed in Japanese Patent Application Laid-Open No. 3-118815 will exhibit the same operation as a rigid body for particles moving at a high speed and the particles will elastically scatter. Hence, it is thought that the particles will reach semiconductor substrate or the like in the vacuum container, thereby having an adverse effect upon yield of semiconductor elements.

However, it has now been discovered that vacuum processors disclosed by Japanese Patent Application Laid-Open Nos. 3-118815 and 2007-180467 cannot restrain degradation of yield in spite of provision of an adhesive material or a flocculent body.

The vacuum processors disclosed by Japanese Patent Application Laid-Open No. 2007-180467 captures particles bounced by pump rotary blades using flocculent body. However, dust generates from a flocculent body and therefore yield of semiconductor elements cannot be restrained from being degraded. A flocculent body used in a vacuum processor is obtained by cutting a large sheet of felt to the size of a connecting pipe. Accordingly, the front end of a flocculent body peripheral part corresponds to a portion to be cut. It is thought that dust is apt to generate from the portion to be cut and therefore yield of semiconductor elements cannot be restrained from being degraded.

### SUMMARY

According to the present invention, a vacuum processor includes: a chamber; a pump which keeps the inside of the chamber in a vacuum state; a connection part which connects the chamber with the pump and is formed with a gas passage therein; and a capturing part having a fibrous substance which is disposed to an inner wall of the connection part to capture a particle passing over the gas passage, the fibrous substance has a surface of woven cloth or unwoven cloth facing the passage, and a peripheral part of the woven cloth or the unwoven cloth is folded to a back side and a front end of the peripheral part is interfolded to the back side.

According to the present invention, the capturing part has a fibrous substance which faces the gas passage in the connection part and is disposed along the passage to capture particles. In the present invention, particles bounced by pump rotary blades collide with the fibrous substance of the capturing part. At this time, the particles are captured in between fibers constituting the fibrous substance.

By providing a fibrous substance facing the gas passage within the connection part in the capturing part in this way, bouncing particles can be restrained, like use of a conventional adhesive material, and particles bounced by the pump rotary blades can be prevented from invading into a chamber. This can restrain degradation of yield of members manufactured with a vacuum processor.

In the present invention, the fibrous substance has the surface of woven cloth or unwoven cloth facing a passage, the peripheral part of the woven cloth or the unwoven cloth is folded to a back side and the front end of the peripheral part is interfolded to the back side. Specifically, in the present invention, the peripheral part front end of the woven cloth or the unwoven cloth constituting the fibrous substance is interfolded to a back side, which restrains exposure of the peripheral part front end. Accordingly, dust generated from the peripheral part front end of the woven cloth or the unwoven cloth constituting the fibrous substance can be restrained from invading into the passage and further the chamber. This enables more restraint of degradation of yield of a member manufactured with the vacuum processor.

In order to suppress generation of particles, it is thought that the peripheral part of woven cloth or unwoven cloth of a fibrous substance is solidified by being impregnated with resin having relatively high corrosion resistance such as polyimide resin. However, in this case, the resin-impregnated portion does not contribute on capturing of particles and further the penetrating width becomes difficult to control, thus reducing an area contributing to capturing of particles. On the contrary, in the case of the present invention, the peripheral part front end of woven cloth or unwoven cloth constituting the fibrous substance is interfolded to the back side, which can restrain reduction in the area contributing to capturing of particles.

### BRIEF DESCRIPTION OF THE DRAWINGS

The above and other objects, advantages and features of the present invention will be more apparent from the following description taken in conjunction with the accompanying drawings, in which:

FIG. 1 is a schematic view of a vacuum processor illustrating a basic configuration according to the present invention;

FIG. 2 is a top view illustrating pump rotary blades;

FIG. 3 is a schematic view illustrating a positional relationship between pump rotary blades and stable blades;

FIG. 4 is a perspective view illustrating a capturing part;

FIG. 5 is a perspective view illustrating a supporting substance of the capturing part;

FIG. 6 is a top view illustrating a fibrous substance;

FIG. 7 is a view illustrating a state where particles are captured by unwoven cloth;

FIG. 8 is a view illustrating a state where particles are captured by woven cloth;

FIG. 9 is a top view of woven substance according to a first embodiment of the present invention;

FIG. 10 is a sectional view of the fibrous substance;

FIG. 11 is a top view of the fibrous substance;

FIG. 12 is a sectional view of a fibrous substance according to a second embodiment of the present invention;

FIG. 13 is a view illustrating a state where particles are not captured by a sheet of woven cloth;

FIG. 14 is a view illustrating a state where particles are captured by a plurality of sheets of woven cloth; and

FIG. 15 is a perspective view illustrating a supporting substance according to a variant of the present invention.

### DETAILED DESCRIPTION OF PREFERRED EMBODIMENTS

Preferred embodiments of the present invention will now be described in accordance with the accompanying drawings. In all the drawings, the same reference numerals/characters are used for the same component and therefore description will not be repeated, as needed.

### [Basic Configuration]

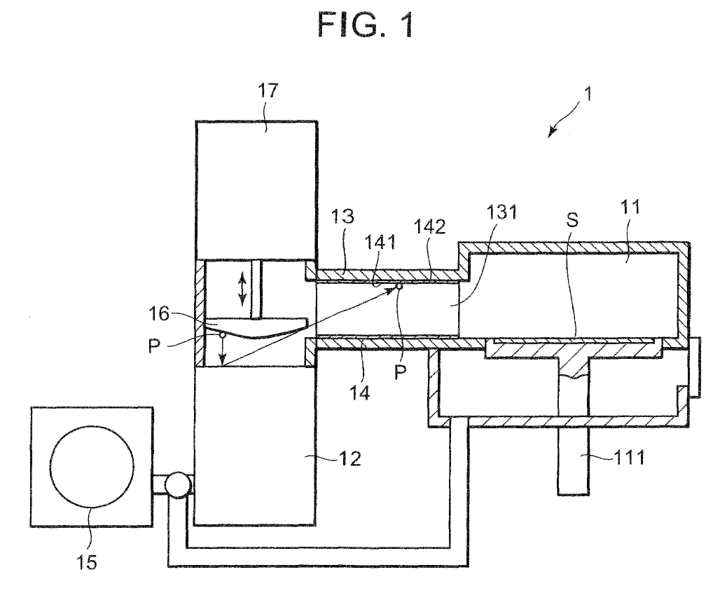

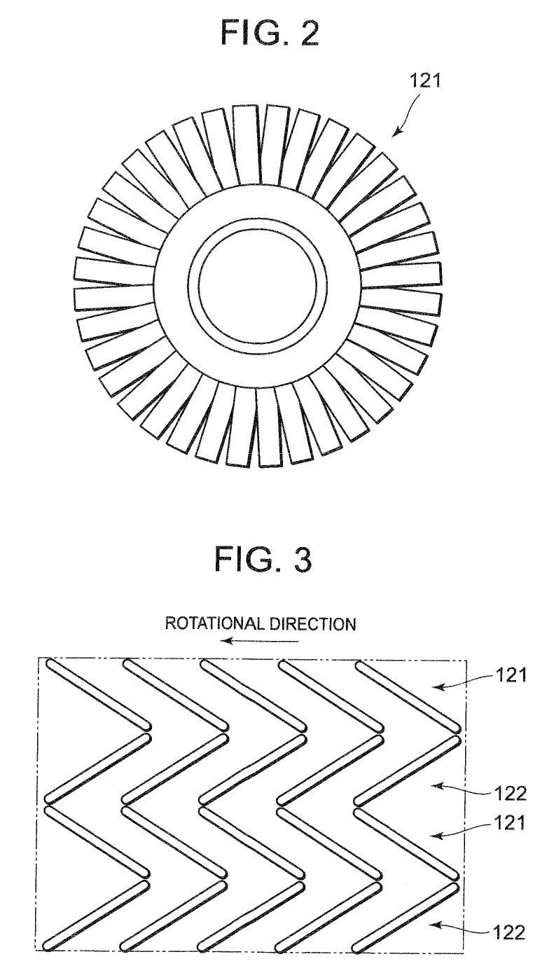

Referring to FIG. 1, description will be made on an outline of a basic configuration of a vacuum processor 1. The vacuum processor 1 includes a chamber 11 and rotary blades 121 (see FIGS. 2 and 3) and further a pump 12 for keeping the inside of the chamber 11 in a vacuum state and a connection part 13 which connects the chamber 11 with the pump 12 and is formed with a gas passage 131 therein. The inner wall of the connection part 13 is formed with a capturing part 14 for capturing particles P in the passage 131 within the connection part 13. The capturing part 14 has a fibrous substance 141 which faces the passage 131 in the connection part 13 and is disposed along the passage 131. The fibrous substance 141 captures particles P.

Next, referring to FIGS. 1 to 8, description will be made in detail on the basic configuration of the vacuum processor 1. As illustrated in FIG. 1, the vacuum processor 1 includes a dry pump 15, a valve 16 and a valve controller 17 in addition to the chamber 11, the pump 12, the connection part 13 and the capturing part 14.

The pump 12 is a turbo molecular pump (TMP) and includes rotary blades 121 and stable blades 122 as illustrated in FIGS. 2 and 3. FIG. 2 is a top view of the rotary blades 121 and FIG. 3 is a schematic view illustrating a positional relationship between the rotary blades 121 and the stable blades 122. The rotary blades 121 and the stable blades 122 are alternately layered and the rotary blades 121 rotate in such a state as to face the stable blades 122, thus performing exhaust processing toward a gas outlet from a gas inlet. A rotational speed of the rotary blades 121 is, for example, 36,000 revolutions/sec and the rotary blades 121 rotates at a very high speed.

As illustrated in FIG. 1, the chamber 11 is a vacuum chamber which has, for example, an object to be processed S such as a semiconductor substrate therein. The semiconductor substrate S in the chamber 11 is placed on a table 111. The inside of the chamber 11 is vacuumed by the pump 12 and, in the chamber 11, for example, treatment, such as plasma etching, is performed.

The dry pump 15 is connected to the pump 12 to exhaust gas to be exhausted from the pump 12. The valve 16 adjusts pressure in the chamber 11 and is driven in a vertical direction in FIG. 1 by the valve controller 17. The valve 16 is placed inside the connection part 13 and is positioned above the pump 12.

The connection part 13 connects the chamber 11 with a gas inlet of the pump 12 and has a gas passage 131 therein. The gas in the chamber 11 is exhausted by the pump 12 through the passage 131 in the connection part 13. In an area where the valve 16 is not disposed, of the passage 131 inside the connection part 13, there is provided the capturing part 14.

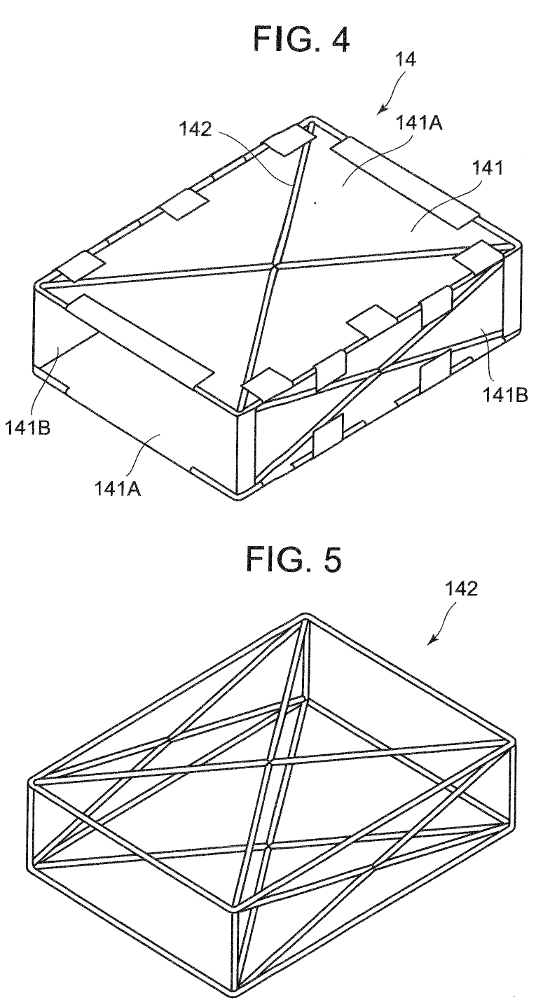

The capturing part 14 captures particles P (e.g. particles of approximately several nm) in the passage 131 within the connection part 13. The particles P exist after cleaning of deposits generated, for example, within the chamber 11. The capturing part 14, as illustrated in FIG. 4, has a fibrous substance 141 and a supporting substance 142 supporting the fibrous substance 141.

The supporting substance 142 has a shape corresponding to an internal shape of the connection part 13 and is fitted into the gas passage 131 in the connection part 13. A face facing the gas passage 131 in the supporting substance 142 is formed with an aperture. As illustrated in FIG. 5, the supporting substance 142 is constructed from a frame 142 of a shape corresponding to the internal shape of the connection part 13. The frame 142 is assembled so as to form a rectangular parallelepiped 3D space. Preferably, the frame 142 is made of, for example, metal or ceramics and more preferably, is made of material having high corrosion resistance. When the supporting substance 142 is inside the connection part 13, the gas passage 131 is positioned inside the supporting substance 142.

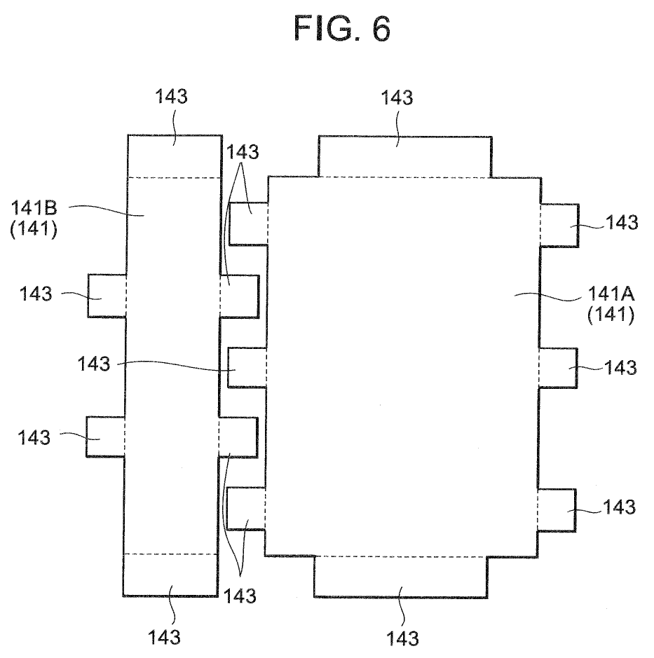

The fibrous substance 141 is placed inside the frame 142 and disposed along the gas passage 131 and facing the passage 131. As illustrated in FIG. 4, the fibrous substance 141 covers a top face, a bottom face and a pair of side faces of a rectangular parallelepiped 3D space formed out of the frame 142. Specifically, as illustrated in FIG. 6, the fibrous substance 141 includes a flat and rectangular fibrous substance 141A covering the top face and the bottom face, respectively and a flat and rectangular fibrous substance 141B covering the side faces.

The fibrous substance 141 may be made of woven or unwoven cloth, but preferably, has unwoven cloth. Use of unwoven cloth where fiber is intertangled in random increases a capturing rate of particles P. A combined use of unwoven cloth and woven cloth is applicable. The aperture ratio, aperture diameter and Metsuke of the fibrous substance 141 may be set according to the size of particles P as needed. Specifically, an aperture ratio, an aperture diameter or Metsuke may be set so as to capture particles P.

The material of the fibrous substance 141 may appropriately be changed according to the type of gas passing through the connection part 13, that is, gas to be used in the chamber 11 or gas used for cleaning the chamber 11, as needed. Preferably, the material of the fibrous substance 141 includes, for example, any of cellulose, glass fiber, alumina ceramics fiber (alumina fiber) and polytetrafluoroethylene fiber. Further, at least two materials therefrom may be included.

Where the chamber 11 is RF etching chamber, mostly inert gas passes through the passage 131 in the connection part 13 and therefore woven or unwoven cloth including cellulose may be used as the fibrous substance 141.

Moreover, where the chamber 11 is an etching chamber for generating plasma by use of corrosive gas such as chlorine and HBr, woven or unwoven cloth including any of glass fiber, alumina ceramics fiber and polytetrafluoroethylene fiber may be used as the fibrous substance 141. Further, when plasma is generated with fluorine gas, woven or unwoven cloth including alumina ceramics fiber may be used as the fibrous substance 141.

The fibrous substance 141 as described above is attached with attachment pieces 143. Each of the attachment pieces 143 is attached to each side of the respective fibrous substances 141. Each attachment piece 143, in attaching the fibrous substance 141 to the inside of the supporting substance 142, is folded back to the outside of the supporting substance 142, and the fibrous substance 141 is firmly attached to the supporting substance 142. A snap or the like may be attached onto each of faces of the back side of the fibrous substance 141 and of the side of the attachment piece 143 which attaches to the fibrous substance 141 to detachably fix the back side of the fibrous substance 141 and the attachment piece 143. The attachment piece 143 may be formed out of not only the same material as the fibrous substance 141 but also different material from the fibrous substance 141.

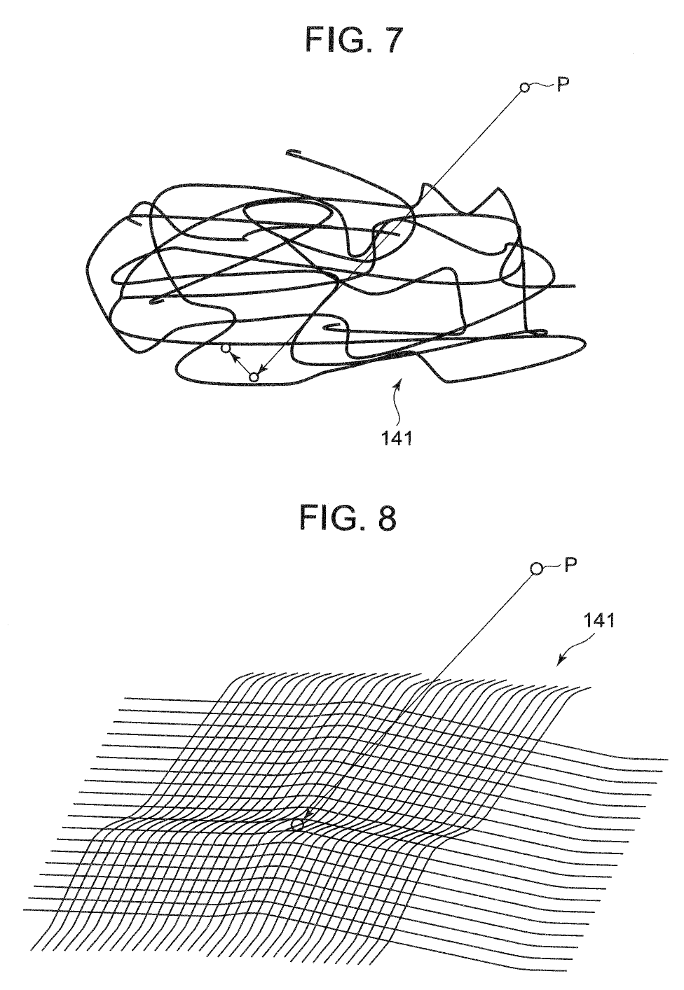

Next, description will be made on capturing of particles P by the capturing part 14. In the vacuum processor 1, particles P may adhere to a peripheral portion of the pump 12. For example, as illustrated in FIG. 1, particles P may adhere to the valve 16. The particles P drop for some reason and collide with the rotary blades 121 of the pump 12. The particles P are bounced by the rotary blades 121 of the pump 12 and bounce about in the gas passage 131 within the connection part 13. The rotary blades 121 of the pump 12 rotate at a high speed, and therefore the speed of particles P is high. When particles P collide with a portion where the capturing part 14 is provided inside the connection part 13, the particles P invade into the fibrous substance 141 of the capturing part 14 and are intertangled between fibers of the fibrous substance 141, as illustrated in FIGS. 7 and 8. FIG. 7 is a schematic view of a fibrous substance 141 made of unwoven cloth and FIG. 8 is a schematic view of a fibrous substance 141 made of woven cloth.

Next, description will be made on operation and advantage in the basic configuration. In the basic configuration, the inner wall of the connection part 13 connecting the chamber 11 with the pump 12 is provided with the capturing part 14 for capturing particles P in the gas passage 131 within the connection part 13. The capturing part 14 has the fibrous substance 141 which faces the gas passage 131 within the connection part 13 and is disposed along the passage 131. The particles P bounced by the rotary blades 121 of the pump 12 collide with the fibrous substance 141 of the capturing part 14. At this time, the particles P invade into between fibers constituting the fibrous substance 141 to be captured. As described above, the capturing part 14 has the fibrous substance 141 facing the gas passage 131 within the connection part 13, and therefore particles P are restrained from bouncing like a conventional adhesive material and the particles P bounced by the rotary blades 121 of the pump 12 are prevented from invading into the chamber 11. Hence, yield of the substance manufactured by use of the vacuum processor 1 is restrained from lowering.

The capturing part 14 has the supporting substance 142 for supporting the fibrous substance 141. The supporting substance 142 is attached to the fibrous substance 141. By fitting the substance into the inside of the connection part 13, the capturing part 14 is arranged inside the connection part 13. This allows the capturing part 14 to be easily arranged in the connection part 13. Because it is sufficient to fit the capturing part 14 into the connection part 13, the capturing part 14 is mounted more easily than a conventional arrangement of the vacuum processor 1.

As a method for attaching the fibrous substance 141 to the inside of the connection part 13, there may be a method for attaching the fibrous substance 141 onto the connection part 13 with adhesives or two-sided adhesive tape. However, in this case, gas may occur from adhesives or two-sided adhesive tape. On the other hand, attachment of the fibrous substance 141 to the supporting substance 142 made of metal or ceramics can avoid generation of gas. Moreover, by fitting the supporting substance 142 to the inside of the connection part 13, the capturing part 14 can be arranged inside the connection part 13. Accordingly, in performing maintenance of the vacuum processor 1, the capturing part 14 can be easily removed from the connection part 13. On the other hand, in the case of use of adhesives or two-sided adhesive tape, maintenance of the vacuum processor 1 needs removal of adhesives or two-sided adhesive tape, and therefore workability of maintenance may degrade.

Further, by attaching an attachment piece 143 to the fibrous substance 141, and the attachment piece 143 and the fibrous substance 141 are detachably fixed by snapping or the like. Detachable fixing by snapping, for example, when the fibrous substance 141 captures a large amount of particles P, allows the fibrous substance 141 to be easily replaced.

### First Embodiment

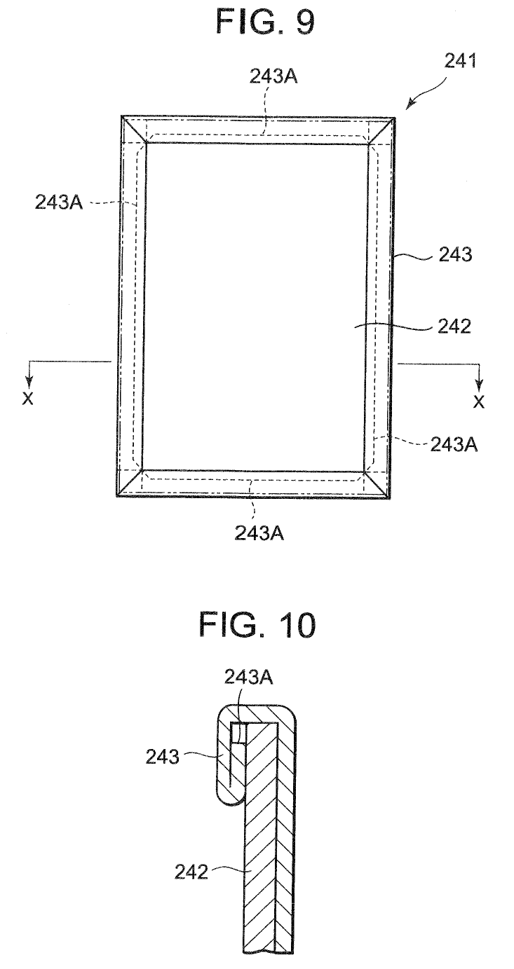

Referring to FIGS. 9 to 11, description will be made on a first embodiment of the present invention below. In the present embodiment, as illustrated in FIG. 9, a fibrous substance 241 includes woven cloth 243 having a surface facing the passage 131 and unwoven cloth 242 having a surface on the passage 131 side covered with the woven cloth 243. The peripheral part of the woven cloth 243 is folded to the back side of the unwoven cloth 242 (also corresponding to the back side of woven cloth 243) and a peripheral part front end 243A of the woven cloth 243 is interfolded to the back side of the unwoven cloth 242. Other respects are the same as for the basic configuration described above.

The unwoven cloth may be formed by a needle punch method. Otherwise, the span bond method, thermal bond method or chemical bond method may be used. Of the above-methods, preferably, the needle punch method is used. Some materials of the unwoven cloth 242 are difficult to cause fusion between fibers, and hence may be difficult to be formed by thermal bond method. In addition, the chemical method, using adhesives such as adhesive resin, may degrade manufacturing stability of a substance manufactured with the vacuum processor 1 due to many impurities included in the unwoven cloth 242. Further, adhesives may be corroded by gas passing through the passage 131. On the other hand, the needle method, requiring no fusion between fabrics, can prevent difficult formation of unwoven cloth. Furthermore, the unwoven cloth formed by the needle punch method, formed by mutual fiber confounding, can prevent an increase in impurities or corrosion of adhesives. The unwoven cloth 242 is flat and rectangular and covers its side space or its upper/lower space, respectively, partitioned by the frame 142 in the paragraph of the basic configuration.

The woven cloth 243 has a surface directly facing the passage 131. The woven cloth 243, of a flat and rectangular shape, covers the whole surface of one face (a surface on the passage 131 side) of the unwoven cloth 242 and has a peripheral part folded to the side of the other face (back face) of the unwoven cloth 242. As illustrated in FIG. 10, the front end 243A of the peripheral part of the woven cloth 243 is folded to the other face side of the unwoven cloth 242 on the other face side of the unwoven cloth 242. In other words, the front end 243A of the peripheral part of the woven cloth 243 is in such a state as not to be exposed. In the present embodiment, the whole periphery of the front end 243A of the peripheral part of the woven cloth 243 is not exposed on the other face side of the unwoven cloth 242. FIG. 10 is a sectional view in an X-X direction illustrated in FIG. 9.

The woven cloth 243 is, for example, if plain weave and preferably, the average aperture diameter is 0.05 mm or more. Preferably, the average aperture diameter of the woven cloth 243 is smaller than the average length of a fiber forming the unwoven cloth 242, for example, 1 mm or less. Moreover, in the case of the unwoven cloth 242 manufactured by the needle punch method, preferably, the length of the unwoven cloth is smaller than that of most of short fiber generated by being cut in a manufacturing process (3σ or less of the mean value of the short fiber after being cut with a needle punch). More preferably, the average aperture diameter is 0.1 mm or more. More preferably, the average aperture diameter is 0.5 mm or less. Specifically, the aperture diameter is 0.3 mm or more and 0.7 mm or less and more preferably, the woven cloth 243 of an approximately 0.4 mm in the average aperture diameter is used. Preferably, the aperture ratio of the woven cloth 243 is 30% or more. Above all, the aperture ratio of the woven cloth 243 is 50% or more and more preferably, 70%. Because of substantial woven cloth, the upper limit of the aperture ratio is limited by the thickness of twist yarn of an aggregate of single fiber forming a weave and an average aperture diameter.

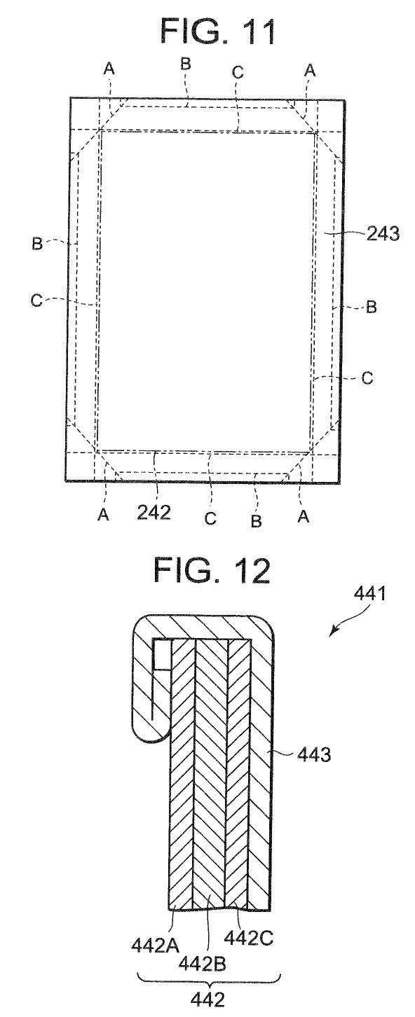

Next, description will be made on a formation method of the fibrous substance 241. As illustrated in FIG. 11, unwoven cloth 242 is placed on one face (back face) of the woven cloth 243. The woven cloth 243 is larger than the unwoven cloth 242 in plane shape. Accordingly, the one (front) face of the unwoven cloth 242 is completely covered with the woven cloth 243. Next, of the peripheral part of the woven cloth 243, a corner portion of the woven cloth 243 is folded to a face (the other face (back)) side on the side not covered with the woven cloth 243 of the unwoven cloth 242 along a dot line A in FIG. 11. Further, the peripheral part of the woven cloth 243 is folded to the other face (back) side of the unwoven cloth 242 along a dot line B. Subsequently, the peripheral part of the woven cloth 243 is interfolded to the other face side (back) of the unwoven cloth 242 along a dot line C. Accordingly, the front end 243A of the peripheral part of the woven cloth 243 is in such a state as not to be exposed on the other face (back) side of the unwoven cloth 242, over the whole periphery. The peripheral part front end of the unwoven cloth 242 is covered with the woven cloth 243 over the whole periphery. Next, the woven cloth 243 and the unwoven cloth 242 are sewed on with yarn. The above processes produce a complete fibrous substance 241.

Subsequently, the attachment piece 143 is attached on the fibrous substance 241 in the same way as the basic configuration and the fibrous substance 241 is fixed onto the supporting substance 142, using the attachment piece 143. At this time, the fibrous substance 241 is fixed onto the supporting substance 142 so that a face which has no exposed unwoven cloth 242 of the fibrous substance 241 and which is completely covered with the woven cloth 243 faces the gas passage 131 within the connection part 13. The above steps make a complete capturing part.

As the materials of the unwoven cloth 242 and the woven cloth 243 according to the present embodiment, the same material as the fibrous substance 141 of the basic configuration described above may be used. For example, cellulose, glass fiber, alumina ceramics fiber or polytetrafluoroethylene fiber may be used. The unwoven cloth 242 and the woven cloth 243 may be formed out of a different material from each other or out of the same material. The yarn for sewing on the unwoven cloth 242 and the woven cloth 243 may use the same material as those of the unwoven cloth 242 and the woven cloth 243.

The present embodiment described above exhibits the same operation and advantage as the basic configuration as well as the following advantages: In the present embodiment, one face of the unwoven cloth 242 is completely covered with the woven cloth 243. The unwoven cloth 242, being kept in such a state that fibers are intertangled with each other in random, as illustrated in FIG. 7, intertangles the particles without bouncing particles P thereby completely capturing particles P, when the particles P collide. However, because the unwoven cloth 242 is not formed by weaving fiber, the fiber forming the unwoven cloth 242 may drop off from the unwoven cloth 242.

By covering one face of the unwoven cloth 242 with the woven cloth 243, fiber of the unwoven cloth 242 is restrained from dropping off. The length of fiber forming the unwoven cloth 242 formed, generally, by the needle punch method, thermal bond method or chemical bond method is longer than 1 mm, and therefore the average aperture diameter of the woven cloth 243 is 1 mm or less, especially 0.5 mm or less, thus preventing fiber of the unwoven cloth 242 from coming off. In the case of the unwoven cloth 242 manufactured by the needle punch method, since the length of fiber shortened after cutting by the needle punch method is approximately 1 mm, the average aperture of the woven cloth 243 makes 1 mm or less, especially 0.5 mm or less, thus completely preventing fiber of the unwoven cloth 242 from coming off.

On the other hand, in a case where the average aperture diameter of the woven cloth 243 is very small, a probability of particles P colliding with yarn of the woven cloth 243 and being bounced on a surface of the woven cloth 243 will become higher than a case where the particles P passes through the woven cloth 243 and are incorporated into the internal unwoven cloth 242. Accordingly, by setting the average aperture diameter of the woven cloth 243 at 0.05 m or more, especially 0.1 mm or more, the particles P are restrained from being bounced by the woven cloth 243. Additionally, by setting the aperture ratio of the woven cloth 243 at 30% or more, especially 50% or more, the particles P can completely pass through the woven cloth 243 and are completely captured by the unwoven cloth 242.

Further, by forming the woven cloth 243 of plain weave, it becomes easy to achieve the average aperture diameter and the aperture ratio, both of which are described above.

In the present embodiment, the front end 243A of the peripheral part of the woven cloth 243 is interfolded to the unwoven cloth 242 side, so as to be kept in a state not exposed to the surface. The front end 243A of the peripheral part of the woven cloth 243 corresponds to a cut portion of the woven cloth 243, and the end of yarn forming the woven cloth 243 is kept in an exposed state. Accordingly, dust such as yarn dust may occur from the front end 243A of the peripheral part of the woven cloth 243.

As found in the present embodiment, the front end 243A of the peripheral part of the woven cloth 243 is interfolded so as to be kept in an unexposed state, thus suppressing generation of dust such as yarn dust from the woven cloth 243. Especially, in the present embodiment, in forming the fibrous substance 241, a corner portion of the woven cloth 243 is folded to the unwoven cloth 242 side along a dot line A. Accordingly, of the front end 243A of the peripheral part of the woven cloth 243, a portion forming a corner portion of the woven cloth 243 is not exposed, thus completely suppressing generation of dust such as yarn dust from the woven cloth 243.

Further, in the present embodiment, the peripheral part of the woven cloth 243 is folded to the back side of the unwoven cloth 242, and therefore the whole periphery of the peripheral part front end of the unwoven cloth 242 is covered with the woven cloth 243, thus suppressing generation of dust from the peripheral part front end of the unwoven cloth 242.

In addition, a method is conceivable for fixing the front end 243A of the peripheral part of the woven cloth 243 by impregnating the front end with resin having relatively high corrosion resistance, such as polyimide resin. However, in this case, even the resin has relatively high corrosion resistance is a little inferior in corrosion resistance to fiber forming the woven cloth 243, such as alumina fiber. Moreover, a portion impregnated with resin does not contribute to capturing of particles P and an impregnating width thereof is difficult to control, and therefore an area contributing to capturing of particles P decreases. On the other hand, in the present embodiment, folding the front end 243A of the peripheral part of the woven cloth 243 can contribute to capturing of particles P over the approximately whole surface of the fibrous substance 241.

### Second Embodiment

Referring to FIG. 12, a second embodiment of the present invention will now be described. In the first embodiment, the fibrous substance 241 has the unwoven cloth 242 and the woven cloth 243. On the other hand, in the present embodiment, a fibrous substance 441 has a first woven cloth 443 having a surface facing a passage 131 and a second woven cloth 442 having a surface on the passage 131 side covered with the first woven cloth 443. Other respects are the same as for the embodiment described above.

The first woven cloth 443 covers the whole surface of one face of the second woven cloth 442 on the passage 131 side, and a peripheral part thereof is folded to the other face of a second woven cloth 442 (back face of the second woven cloth 442, also corresponding to back side of the first woven cloth 443) and the peripheral part front end of the first woven cloth 443 is interfolded to the other face side of the second woven cloth 442. The way of folding the peripheral part of the first woven cloth 443 according to the present embodiment is the same as that of the woven cloth 243 according to the first embodiment. Specifically, in the present embodiment as well, the whole periphery of the peripheral part front end of the first woven cloth 443 is not exposed. The peripheral part front end of the second woven cloth 442 is covered with the first woven cloth 443 over the whole periphery.

The second woven cloth 442 may be of a single sheet or, as illustrated in FIG. 12, may be a layered body of a plurality of sheets, for example, three sheets of woven cloth of 442A to 442C. In forming the second woven cloth 442 out of one sheet of woven cloth, an aperture ratio thereof is smaller than that of the first woven cloth 443, preferably.

Woven cloth 442A to 442C forming the second woven cloth 442 and the first woven cloth 443 are 30% or more in aperture ratio, respectively, preferably 50% or more and more preferably 70% or more. In addition, for perfect prevention of particles bouncing, preferably, yarn forming the respective woven cloth 442A to 442C and 443 is not completely overlapped in the longitudinal direction. The second woven cloth 442 is of bias weave out of one of the sheets of the woven cloth 442A to 442C and of plain weave out of the other two. The materials of the second woven cloth 442 and the first woven cloth 443 can use the same as those described in the paragraph of the basic configuration and the above-mentioned embodiment. The second woven cloth 442 and the first woven cloth 443 may be formed out of a different material or the same material. Furthermore, the woven cloth 442A to 442C may be formed out of a different material from each other or the same material.

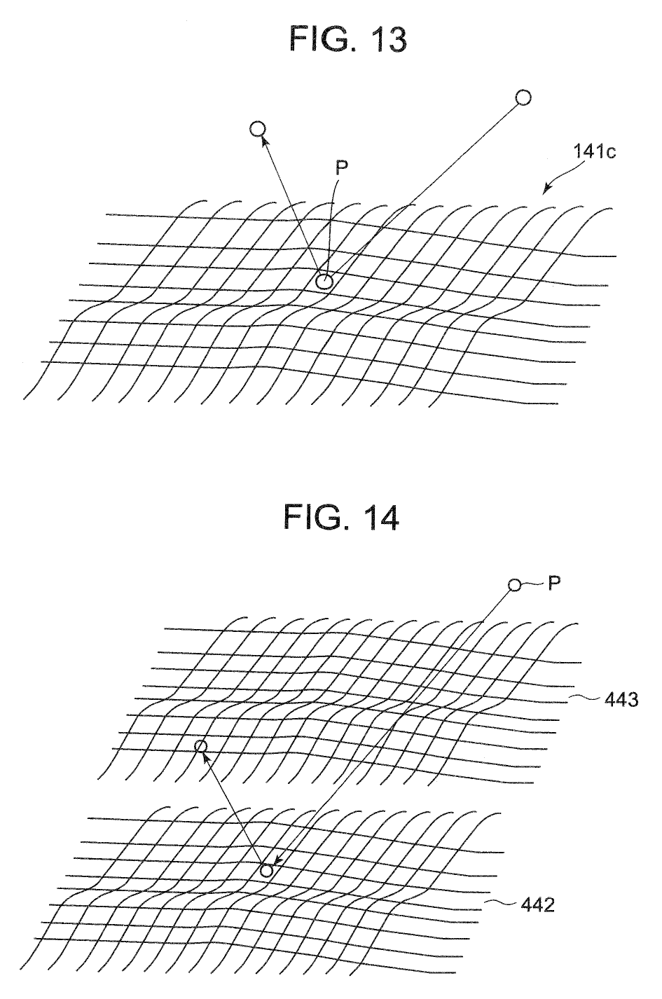

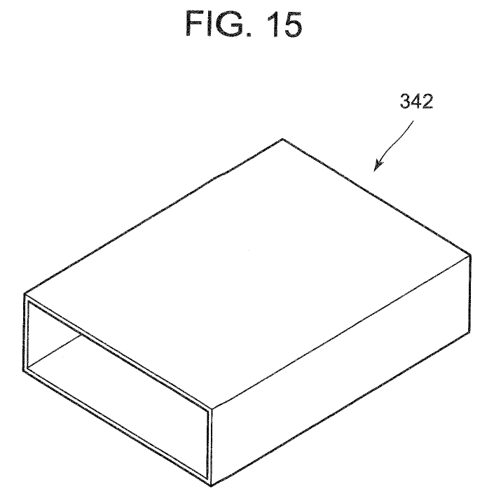

The second embodiment provides the approximately same advantage as the first embodiment as well as the following advantages: In the present embodiment, the fibrous substance is formed by laminating a plurality of sheets of woven cloth, thus increasing the capturing rate of particles P. As illustrated in FIG. 13, in the case of one sheet of woven cloth 141C, the particles P invading into an aperture between yarns of the woven cloth 141C bounce and may go out of the aperture. On the other hand, as illustrated in FIG. 14, by laminating a plurality of sheets of woven cloth 443, 442, particles P can be restrained from invading into the inside of a laminated body of the woven cloth, bouncing, colliding with yarn of the woven cloth 443 of an upper layer and going out of the fibrous substance. Especially, no complete overlapping of yarn in a longitudinal direction can further increase the capturing rate of particles P.

It is understood that the present invention is not limited to the foregoing embodiments and various modifications and variations of the present invention may be made without departing from the spirit and scope thereof. For example, the respective embodiments described above use a frame 142 as a supporting substance, which is not limited thereto. For example, as illustrated in FIG. 15, a bottomless cylindrical supporting substance 342 having a shape corresponding to an internal shape of a connection part may be used. In this case, an aperture of the supporting substance 342 is disposed so as to face a gas passage 131. It is sufficient to form the supporting substance 342 into a cylindrical shape out of a material such as plate or ceramics. Fibrous substances 141, 241, 441 are arranged inside the supporting substance 342 and the attachment piece 143 is folded back to the outside of the supporting substance 342. The supporting substance 342 illustrated in FIG. 15 may be formed out of the same material as fibrous substances 141, 241, 441. The supporting substance 342 is formed into a cylindrical shape out of a thick and rigid fibrous material. In this case, the fibrous substances 141, 241, 441 are sewed onto the inside of the supporting substance 342.

In the basic configuration and the respective embodiments described above, the fibrous substances 141, 241, 441 are arranged inside the frame 142, which is not limited thereto, and the fibrous substances may be outside the frame 142.

In this case, the attachment piece 143 passes through the inside of the frame 142 (gas passage 131 side) of the frame 142, protrudes from the frame 142 and is folded back to the outside of the frame 142. However, by arranging the fibrous substances 141, 241, 441 inside the frame 142 as found in the respective embodiments described above, particles P can be prevented from colliding with the frame 142.

The basic configuration and the respective embodiments described above use a supporting substance 142 for supporting the fibrous substances 141, 241, 441, which is not limited thereto, and the fibrous substances may be attached onto the inner wall of the connection part 13, using two-sided adhesive tape or adhesives. However, if the corrosion resistance of two-sided adhesive tape or adhesives is insufficient, the frequency of maintenance may become high. Further, in the case of use of adhesives or two-sided adhesive tape, a fibrous substance is required to be removed from the inner wall of the connection part 13, and therefore workability of maintenance may degrade. However, the number of constitutional components of the capturing part can be reduced.

In the respective embodiments described above, a laminated body of unwoven cloth and woven cloth or a laminated body of a plurality of sheets of woven cloth has been used as fibrous substances 241, 441, which is not limited thereto, but the fibrous substance may be formed out of a sheet of unwoven cloth or woven cloth. The number of sheets of unwoven cloth according to the first embodiment is not limited to one and a plurality of sheets may be used. In addition, as the fibrous substance, a laminated body formed by laminating a plurality of sheets of unwoven cloth may be used. Further, it has been described that, in the first embodiment, unwoven cloth is preferably formed by the needle punch method, which is not limited thereto, the unwoven cloth may be formed according to any of the following methods: a method in which, after air is applied to long fiber cut to several centimeters before distribution, water is applied to increase density for sandwiching and drying, a method in which long fiber is distributed in the water, skewing is performed like paper skewing, the fiber is formed into a sheet shape with high density to some degree and sandwiching is performed before drying, or a method in which fiber is intertangled by using shower of fine and high-speed water stream in place of needle.

It is apparent that the present invention is not limited to the above embodiments, but may be modified and changed without departing from the scope and spirit of the invention.

What is claimed is:

1. A vacuum processor comprising:
a chamber;
a pump keeping inside of the chamber in a vacuum state;
a connection part connecting the chamber with the pump and being a gas passage inside the connection part; and
a capturing part having a fibrous substance which is disposed to an inner wall of the connection part to capture a particle passing over the gas passage,
wherein the fibrous substance has a surface of woven cloth or unwoven cloth facing the passage and
a peripheral part of the woven cloth or the unwoven cloth is folded to a back side and a front end of the peripheral part is interfolded to the back side.

2. The vacuum processor according to claim 1, wherein
the fibrous substance comprises a plurality of sheets selecting from woven cloth and unwoven cloth.

3. The vacuum processor according to claim 2, wherein
the fibrous substance includes a woven cloth having a surface facing the passage, and
an unwoven cloth having a surface on the passage side, covered with the woven cloth,
a peripheral part of the woven cloth is folded to the back side of the unwoven cloth, and
a peripheral part front end of the woven cloth is interfolded to the back side.

4. The vacuum processor according to claim 3, wherein
the woven cloth of the fibrous substance has an average aperture diameter of 0.05 mm or more and 1 mm or less.

5. The vacuum processor according to claim 3, wherein
an aperture ratio of the woven cloth of the fibrous substance is 30% or more.

6. The vacuum processor according to claim 3, wherein
the unwoven cloth is obtained by the needle punch method.

7. The vacuum processor according to claim 2, wherein
the fibrous substance includes a first woven cloth having a surface facing the passage, and
a second woven cloth having a surface on the passage side, covered with the first woven cloth,
a peripheral part of the first woven cloth is folded to the back side of the second woven cloth, and
a peripheral part front end of the first woven cloth is interfolded to the back side of the second woven cloth.

8. The vacuum processor according to claim 7, wherein
the second woven cloth is formed by a plurality of sheets of woven cloth.

9. The vacuum processor according to claim 1, wherein
the woven cloth or the unwoven cloth includes at least one fiber selecting from cellulose, glass fiber, alumina ceramics fiber and polytetrafluoroethylene fiber.

10. The vacuum processor according to claim 1, wherein
the capturing part includes: the fibrous substance and
a supporting substance being disposed in the gas passage of the connection part, having an aperture on a face facing the gas passage and supporting the fibrous substance.

11. The vacuum processor according to claim 10, wherein
the supporting substance has a frame compatible with an internal shape of the connection part, and
the fibrous substance is placed on the frame.

12. The vacuum processor according to claim 10, wherein
the supporting substance has a shape compatible with an internal shape of the connection part and is a bottomless tubular body having an open face facing the gas passage, and
the fibrous substance is disposed so as to cover an internal face of the supporting substance.

13. The vacuum processor according to claim 11, wherein
the fibrous substance is provided with an attachment piece which protrudes from the supporting substance, is folded back to the outside of the supporting substance and attaches the fibrous substance to the supporting substance.

14. The vacuum processor according to claim 13, wherein
the supporting substance has a frame compatible with an internal shape of the connection part,
the fibrous substance is placed on the frame, and
the attachment piece protrudes from the frame, is folded back to the outside of the frame and is detachably fixed on the back of the fibrous substance.

15. The vacuum processor according to claim 1, wherein
the pump includes rotary blades.
